(19) United States
(12) Patent Application Publication
(10) Pub. No.: US 2006/0226526 A1
(43) Pub. Date: Oct. 12, 2006

(54) Microcontroller internal data capture and display

(75) Inventor: James E. Bartling, Chandler, AZ (US)

Correspondence Address: BAKER BOTTS, LLP, 910 LOUISIANA, HOUSTON, TX, 77002-4995, US

(73) Assignee: Microchip Technology Incorporated

(21) Appl. No.: 11/352,026

(22) Filed: Feb. 10, 2006

Related U.S. Application Data
(60) Provisional application No. 60/655,932, filed on Feb. 24, 2005.

(51) Int. Cl. H01L 23/02

(52) U.S. Cl. 257/686

(57) ABSTRACT

Capture and monitoring of critical data from a microcontroller is performed without halting or changing normal program execution therein. Data is captured according to stored program addresses that may run in the background during operation of the microcontroller. When an address match occurs data may thereby be captured. The captured data may be output via an in-circuit debugger (ICD) interface to a workstation computer. Therefore, a program emulator is no longer necessary for program evaluation and debugging purposes.

### RELATED PATENT APPLICATION

This application claims priority to commonly owned U.S. Provisional Patent Application Ser. No. 60/655,932; filed Feb. 24, 2005; entitled “Microcontroller Internal Capture And Display,” by James E. Bartling; which is hereby incorporated by reference herein for all purposes.

### TECHNICAL FIELD

The present disclosure relates to microcontrollers, more particularly, to internal capture and display of critical data from the microcontroller without halting or changing program operation of the microcontroller.

### BACKGROUND

In trying to debug closed loop control systems a user cannot stop operation of the controller to monitor the internal data being used in the control scheme without disturbing the control loop. Heretofore, expensive emulator systems have been used to simulate operation of the control system or instructions have been added to the control program so as to be able to look at data while the control program is running. However, adding instructions to the control program of the control system may disturb proper operation thereof.

### SUMMARY

Therefore, what is needed is a way to monitor data being used in a control program of a control system without requiring expensive emulator systems, breaking, halting or modifying the control program, or adding instructions to the control program. According to teachings of this disclosure, a user may capture and monitor critical control program data from a microcontroller without halting normal program execution therein. Monitoring may occur in the background during normal operation of the microcontroller and when a trigger event occurs appropriate data may be captured. The captured data may be processed with an in-circuit debugger (ICD) interface and made available for evaluation purposes through a data port, e.g., serial data bus. The ICD may be integral with the microcontroller and provide features normally found in high end emulators. Therefore, a program emulator is no longer necessary for program evaluation and debugging purposes since the microcontroller ICD may provide all real time data necessary for program evaluation and debugging purposes.

According to a specific example embodiment of the present disclosure, an apparatus for internal data capture and display having a microcontroller that may comprise a processor, a memory, and at least one input; and an in-circuit debugger (ICD) module that may comprise a plurality of capture registers, an ICD control, an address comparator, an address table and a serial data transceiver, wherein the processor is coupled to the memory and the address comparator with an address bus, and to the memory and the plurality of capture registers with a data bus; whereby data associated with addresses stored in the address table are captured in the plurality of capture registers.

According to another specific example embodiment of the present disclosure, a method for capturing internal data of a microprocessor without halting or changing program operation thereof may comprising the steps of: loading into an address table addresses of data to be captured; monitoring an address bus of a microcontroller while the microcontroller is executing a control program; comparing addresses on the address bus to the addressees loaded into the address table; and storing data into a plurality of capture registers whenever the addresses on the address bus match the addresses loaded into the address table, where the stored data are associated with the addresses loaded into the address table.

### BRIEF DESCRIPTION OF THE DRAWINGS

A more complete understanding of the present disclosure thereof may be acquired by referring to the following description taken in conjunction with the accompanying drawings wherein:

FIG. 1 is a schematic block diagram of an in-circuit debugger (ICD) system and ICD capable microcontroller, according to a specific example embodiment of the present disclosure; and

FIG. 2 is a more detailed schematic block diagram of the ICD capable microcontroller shown in FIG. 1, according to a specific example embodiment of the present disclosure.

While the present disclosure is susceptible to various modifications and alternative forms, specific example embodiments thereof have been shown in the drawings and are herein described in detail. It should be understood, however, that the description herein of specific example embodiments is not intended to limit the disclosure to the particular forms disclosed herein, but on the contrary, this disclosure is to cover all modifications and equivalents as defined by the appended claims.

### DETAILED DESCRIPTION

Referring now to the drawings, the details of example embodiments are schematically illustrated. Like elements in the drawings will be represented by like numbers, and similar elements will be represented by like numbers with a different lower case letter suffix.

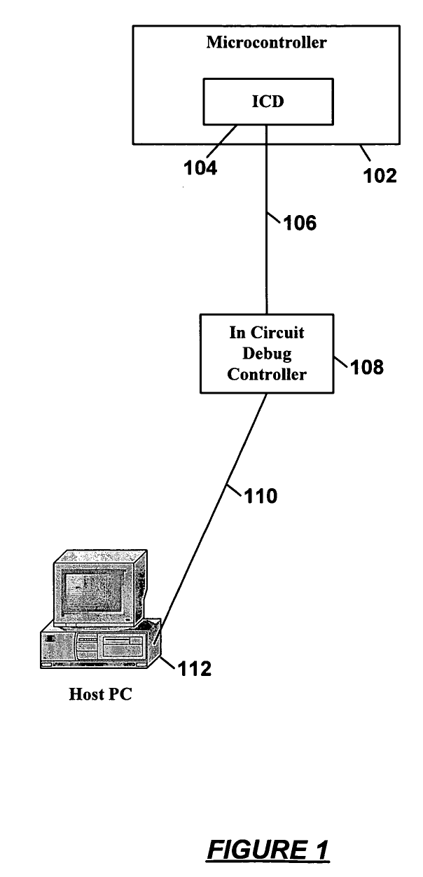

Referring to FIG. 1, depicted is a schematic block diagram of an in-circuit debugger (ICD) system and ICD capable microcontroller, according to a specific example embodiment of the present disclosure. The ICD system, generally represented by the numeral 100, may comprise a host personal computer (PC) 112 and an ICD controller 108, e.g., MPLAB unit. The host PC 112 may communicate with the ICD controller 108 over a serial data bus 110, e.g., Universal Serial Bus (USB).

An ICD module 104 may be associated with a microcontroller 102, e.g., both fabricated and interconnected on the same integrated circuit die (not shown). The ICD module 104 may comprise a serial debug port such as one available on most production devices (e.g., microcontrollers 102) for in-system use. The ICD controller 108 may be coupled to a serial debug port of the ICD module 104 over a serial test bus 106, e.g., ICD cable to an ICD header connector.

The ICD module 104 may provide most of the software debugging tools required. The ICD controller 108 in combination with the ICD module 104 may provide code downloading and verification to FLASH memory devices in the microcontroller 102 (not shown), halt and break pointing, animated single-step execution and resource examination. The ICD controller 108 may translate commands from the host PC 112 into commands recognizable by the microcontroller 102 in an in-circuit debugger (ICD) mode. The ICD controller 108 may also be used to program the microcontroller 102.

When the ICD module 104 is enabled it may monitor all trap events, provide trap controls, generate trap interrupts, and a wake-up event to the core of the microcontroller 102. In addition to trap events, trigger events may also be generated using break point register sets. A trigger event may also be used to start or stop a cycle counter, or capture and output data.

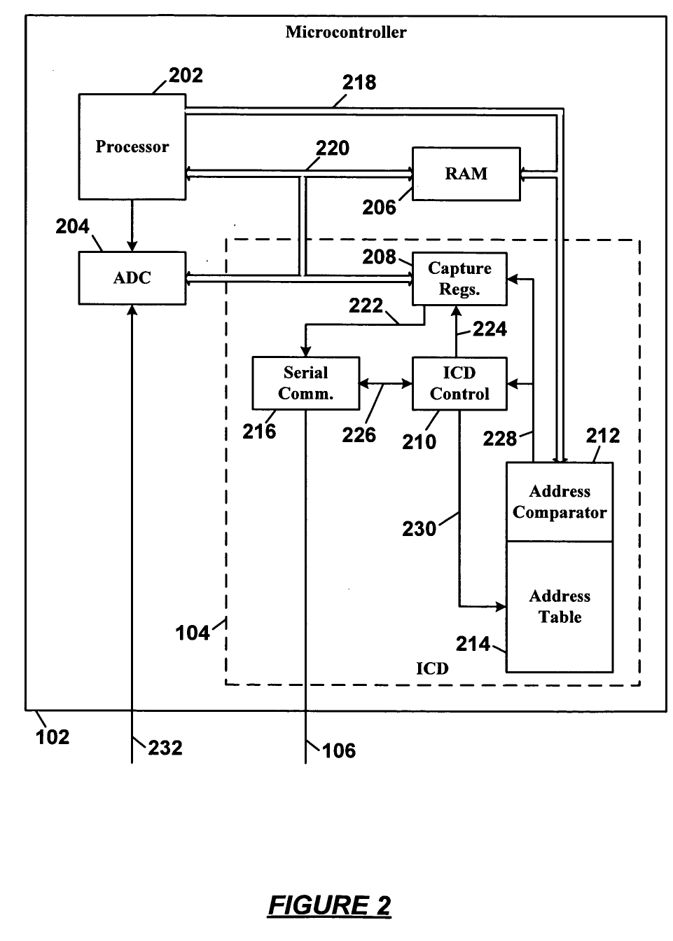

Referring to FIG. 2, depicted is a more detailed schematic block diagram of the ICD capable microcontroller shown in FIG. 1, according to a specific example embodiment of the present disclosure. The microcontroller 102 may comprise a processor 202, an analog-to-digital converter (ADC) 204, a random access memory (RAM) 206, and the ICD 104. Not shown but also contemplated and within the scope of this disclosure are digital inputs and outputs associated with the processor 202. The ICD 104 may comprise capture registers 208, ICD control 210, an address comparator 212, an address table 214, and a serial data transceiver 216.

The processor 202 may control address information to the RAM 206 and address comparator 212 over an address bus 218. Data may be available to the processor 202, ADC 204, RAM 206 and capture registers 208 over a data bus 220. Typically, a real-time analog signal, e.g., from an input sensor of a control loop, may be received on an analog input 232, wherein the ADC 204 converts the analog input signal to a digital representation thereof and outputs this digital representation onto the data bus 220. More than one analog signal may be converted to digital representations by the ADC 204 (e.g., using analog input multiplexers and/or multiple sample and hold analog input channels) and output to the data bus 220. The processor 202 may control operation of the ADC 204. The processor 202 may also output at least one analog signal with a digital to analog converter (DAC) (not shown), e.g., for control of an analog loop. It is contemplated and within the scope of this disclosure that digital inputs representing analog signal values may also be input (and output) to (from) the processor 202 and data bus 220, e.g., pulse width modulation (PWM) signals for use in control loops of electronic equipment, e.g., power supply output voltage regulation and/or current control. It is also contemplated and within the scope and teachings of this disclosure that any control program running in a microcontroller may be monitored with the IDC 104.

In a closed loop control system, an analog input representing a process variable, e.g., voltage of a power supply, is evaluated so that a circuit supplying that process variable may be controlled for maintaining the process variable at a desired value. Many factors may affect reaction time and transient response of a closed loop control system. However, the monitoring, feedback and control logic, e.g., ADC 204 (input), processor 202 and an analog output (or PWM output) (not shown) all have to function within certain time parameters, otherwise the loop response time and/or loop stability may not function properly. Therefore it is imperative that any type of loop control program evaluation, monitoring, debugging, etc., does not significantly affect any timing relationships established in the control program running in the processor 202. It is also desirable that monitoring of the control loop parameters be obtained contemporaneously (e.g., in real time) without disturbing the normal operational timing of the control program.

The address table 214 may be used to store the addresses at which the data of interest may be located so that this data may be made available contemporaneously during control program execution for testing, evaluation and/or debugging of the control program. Whenever an address stored in the address table 214 matches an address on the address bus 218, the address comparator 212 may indicate the match to the ICD control 210 (e.g., address match signal 228). Once the ICD control 210 receives the address match signal 228, the ICD control 210 may have the capture registers 208 capture data values from the data bus 220 relating to that address. A plurality of data values corresponding to the addresses stored in the address table 214 may thereby be captured and stored in the capture registers 208. The capture registers 208 may output the captured data stored therein to the serial data transceiver 216 for transmission to the ICD controller 108 and ultimately to the host PC 112 for interfacing with the user. The address comparator 212 may also be used to recognize break points (addresses) in the control program for halting and/or trapping the control program running in the processor 202.

In addition, the ICD 104 may associate tag numbers (e.g., address table address locations) with the data captured in the plurality of capture registers 208. The ICD control 210 may cause the serial data transceiver 216 to send the associated tag numbers (e.g., over control bus 226) with the captured data from the plurality of capture registers 208.

Either certain ones of the plurality of capture registers 208 and/or separate registers (not shown) may be used as break point registers for storing addresses that may indicate occurrences of events, e.g., trap events, trigger events, etc., for starting and/or stopping a cycle counter, and/or capturing and outputting data.

While embodiments of this disclosure have been depicted, described, and are defined by reference to example embodiments of the disclosure, such references do not imply a limitation on the disclosure, and no such limitation is to be inferred. The subject matter disclosed is capable of considerable modification, alteration, and equivalents in form and function, as will occur to those ordinarily skilled in the pertinent art and having the benefit of this disclosure. The depicted and described embodiments of this disclosure are examples only, and are not exhaustive of the scope of the disclosure.

What is claimed is:

1. An apparatus for internal data capture and display, comprising:
a microcontroller comprising
a processor,
a memory, and
at least one input; and
an in-circuit debugger (ICD) module comprising
a plurality of capture registers,
an ICD control,
an address comparator,
an address table and
a serial data transceiver,
wherein
the processor is coupled to the memory and the address comparator with an address bus, and
to the memory and the plurality of capture registers with a data bus;
whereby data associated with addresses stored in the address table are captured in the plurality of capture registers.

2. The apparatus according to claim 1, wherein the data captured in the plurality of capture registers is transferred to an in-circuit debugger (ICD) system over a data transceiver.

3. The apparatus according to claim 2, wherein the data transceiver is a serial data transceiver.

4. The apparatus according to claim 2, wherein each of the plurality of capture registers has an associated tag number and the associated tag numbers are transferred to the ICD system with respective ones of the data captured in the plurality of capture registers.

5. The apparatus according to claim 1, further comprising trap event monitoring with the ICD module.

6. The apparatus according to claim 1, further comprising breakpoint registers for controlling trigger events with the ICD module.

7. The apparatus according to claim 6, wherein a one of the trigger events starts a cycle counter.

8. The apparatus according to claim 6, wherein a one of the trigger events stops a cycle counter.

9. The apparatus according to claim 6, wherein the breakpoint registers are certain ones of the plurality of capture registers.

10. The apparatus according to claim 1, wherein the at least one input is at least one analog input.

11. The apparatus according to claim 1, further comprising at least one output.

12. The apparatus according to claim 1, wherein the at least one output is at least one analog output.

13. The apparatus according to claim 1, wherein the at least one output is at least one pulse width modulation (PWM) output.

14. A method for capturing internal data of a microprocessor without halting or changing program operation thereof, comprising the steps of:
loading into an address table addresses of data to be captured;
monitoring an address bus of a microcontroller while the microcontroller is executing a control program;
comparing addresses on the address bus to the addressees loaded into the address table; and
storing data into a plurality of capture registers whenever the addresses on the address bus match the addresses loaded into the address table, where the stored data are associated with the addresses loaded into the address table.

15. The method according to claim 14, further comprising the step of transferring the stored data to an in-circuit debugger (ICD) system.

16. The method according to claim 15, wherein the step of transferring the stored data comprises the step of transferring the stored data with a serial data transceiver.

17. The method according to claim 14, further comprising the step of associating a tag number with each of the data stored in the plurality of capture registers.

18. The method according to claim 17, further comprising the step of transferring the stored data and the associated tag numbers to an in-circuit debugger (ICD) system.

19. The method according to claim 14, further comprising the step of monitoring a trap event.

20. The method according to claim 19, wherein the step of monitoring a trap event further comprises the step of controlling a trigger event.

21. The method according to claim 20, wherein the step of controlling a trigger event further comprises the step of starting a cycle counter.

22. The method according to claim 20, wherein the step of controlling a trigger event further comprises the step of stopping a cycle counter.
